(19) United States
(12) Patent Application Publication
(10) Pub. No.: US 2025/0125293 A1
(43) Pub. Date: Apr. 17, 2025

(54) SEMICONDUCTOR PACKAGE HAVING IMPROVED THERMAL CHARACTERISTICS

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/789,098

(22) Filed: Jul. 30, 2024

(30) Foreign Application Priority Data
Oct. 12, 2023 (KR) 10-2023-0136224
Dec. 7, 2023 (KR) 10-2023-0176775

(51) Int. Cl. H01L 23/00; H01L 21/48; H01L 23/367; H01L 23/498; H01L 25/18; H10B 80/00

(52) U.S. Cl. CPC H01L 24/08; H01L 21/4857; H01L 21/486; H01L 23/3672; H01L 23/49833; H01L 23/49838; H01L 24/80; H01L 25/18; H01L 2224/08225; H01L 2224/80895; H01L 2224/80896; H01L 2924/1431; H01L 2924/1437; H10B 80/00

(57) ABSTRACT

A semiconductor package includes a substrate including: a substrate comprising a through-hole; a first semiconductor chip in the through-hole; an adhesive layer on a side surface of the first semiconductor chip in the through-hole; a first redistribution structure on an upper surface of the substrate and bonded and connected to the substrate; a second redistribution structure on a lower surface of the substrate and bonded and connected to the substrate; a second semiconductor chip on the first redistribution structure; and a through-via spaced apart from the first semiconductor chip in a horizontal direction and passing through the substrate in a vertical direction.

### CROSS-REFERENCE TO RELATED APPLICATION

This application is based on and claims priority under 35 U.S.C. § 119 to Korean Patent Application Nos. 10-2023-0136224, filed on Oct. 12, 2023, and 10-2023-0176775, filed on Dec. 7, 2023, in the Korean Intellectual Property Office, the disclosures of which are incorporated by reference herein in their entireties.

### BACKGROUND

The disclosure relates to a semiconductor package and a method of manufacturing the same, and more particularly, to a semiconductor package manufactured through hybrid bonding.

In recent years, the electronics market has seen a dramatic increase in the demand for portable devices, which has led to an ongoing need for miniaturization and light-weighting of electronic components in these devices. In order to reduce the size and weight of the electronic components, semiconductor packages including the electronic components are becoming smaller and smaller in volume. However, the electronic components in these semiconductor packages are still required to process a large amount of data. As the semiconductor packages become smaller and lighter, dissipation of heat generated inside the semiconductor packages needs be addressed.

### SUMMARY

The disclosure provides a semiconductor package having improved thermal characteristics and a method of manufacturing the same.

The objects of the disclosure are not limited to the object mentioned above, but other objects not described herein will be clearly understood by those skilled in the art from the following description.

According to an aspect of the disclosure, there is provided a semiconductor package which may include: a substrate comprising a through-hole; a first semiconductor chip in the through-hole; an adhesive layer on a side surface of the first semiconductor chip in the through-hole; a first redistribution structure on an upper surface of the substrate and bonded and connected to the substrate; a second redistribution structure on a lower surface of the substrate and bonded and connected to the substrate; a second semiconductor chip on the first redistribution structure; and a through-via spaced apart from the first semiconductor chip in a horizontal direction and passing through the substrate in a vertical direction.

According to another aspect of the disclosure, there is provided a method of manufacturing a semiconductor package. The method may include: preparing a substrate comprising a hole; forming an adhesive layer on the substrate and attaching a first semiconductor chip into the hole using the adhesive layer; forming a through-via spaced apart from the first semiconductor chip in a horizontal direction and passing through the substrate in a vertical direction; forming a first redistribution structure on an upper surface of the substrate such that the first redistribution structure is directly bonded and connected to the substrate; attaching a second semiconductor chip onto the first redistribution structure such that the second semiconductor chip is directly bonded and connected to the first redistribution structure; and forming a second redistribution structure on a lower surface of the substrate such that the second redistribution structure is directly bonded and connected to the substrate.

According to still another aspect of the disclosure, there is provided a semiconductor package which may include: a substrate including a through-hole; a through-via spaced apart from the through-hole in a horizontal direction and passing through the substrate in a vertical direction; a first semiconductor chip in the through-hole, the first semiconductor chip comprising a memory device; an adhesive layer on a side surface of the first semiconductor chip in the through-hole; a first redistribution structure on an upper surface of the substrate, the first redistribution structure comprising a first insulating layer, a first circuit wiring layer, a first upper connection pad, and a first lower connection pad; a second redistribution structure on a lower surface of the substrate, the second redistribution structure comprising a second insulating layer, a second circuit wiring layer, a second upper connection pad, and a second lower connection pad; a second semiconductor chip on the first redistribution structure and comprising a logic device; and a heat dissipation chip overlapping the first semiconductor chip and the second semiconductor chip in the vertical direction, wherein the first redistribution structure, the first semiconductor chip, the second redistribution structure, and the second semiconductor chip are stacked in the vertical direction, wherein the first semiconductor chip is directly bonded and connected to the first redistribution structure and the second redistribution structure, wherein the through-via is directly bonded and connected to the first redistribution structure and the second redistribution structure, and wherein the second semiconductor chip is directly bonded and connected to the first redistribution structure.

### BRIEF DESCRIPTION OF DRAWINGS

Embodiments will be more clearly understood from the following detailed description taken in conjunction with the accompanying drawings in which:

FIGS. 1A and 1B are side cross-section views schematically showing a semiconductor package, according to one or more embodiments; and

FIGS. 2 to 14 are side cross-sectional views schematically showing a method of manufacturing the semiconductor package, according to one or more embodiments.

### DETAILED DESCRIPTION OF EMBODIMENTS

Hereinafter, embodiments of the disclosure are described in detail with reference to the accompanying drawings. The embodiments described herein are non-limiting example embodiments, and thus, the disclosure is not limited thereto and may be realized in various other forms.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present

It will be understood that, although the terms first, second, third, fourth, etc. may be used herein to describe various elements, components, regions, layers and/or sections (collectively “elements”), these elements should not be limited by these terms. These terms are only used to distinguish one element from another element. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. Herein, the terms “upper surface” and “lower surface” may refer to “top surface” and “bottom surfaces,” respectively. The same reference numerals are given to the same elements in the drawings, and repeated descriptions thereof are omitted.

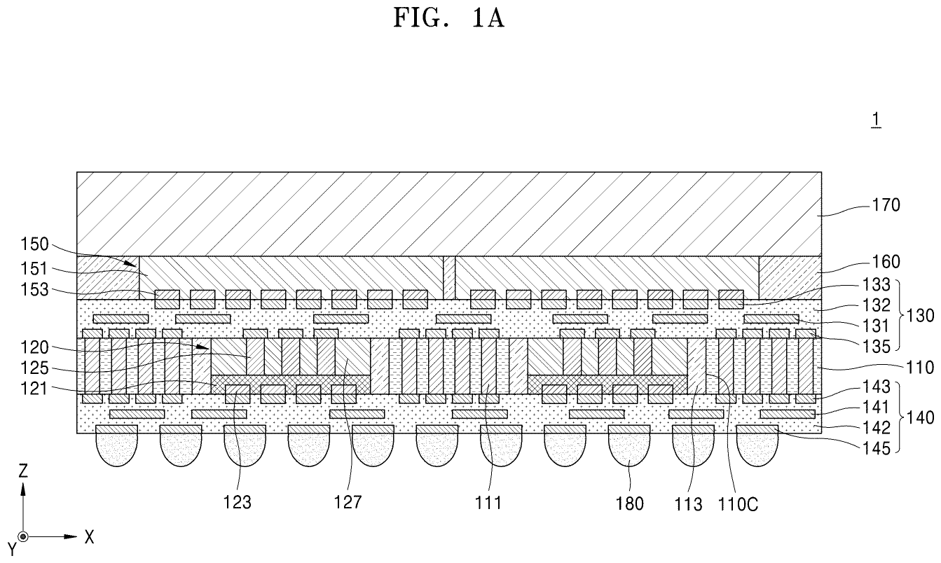

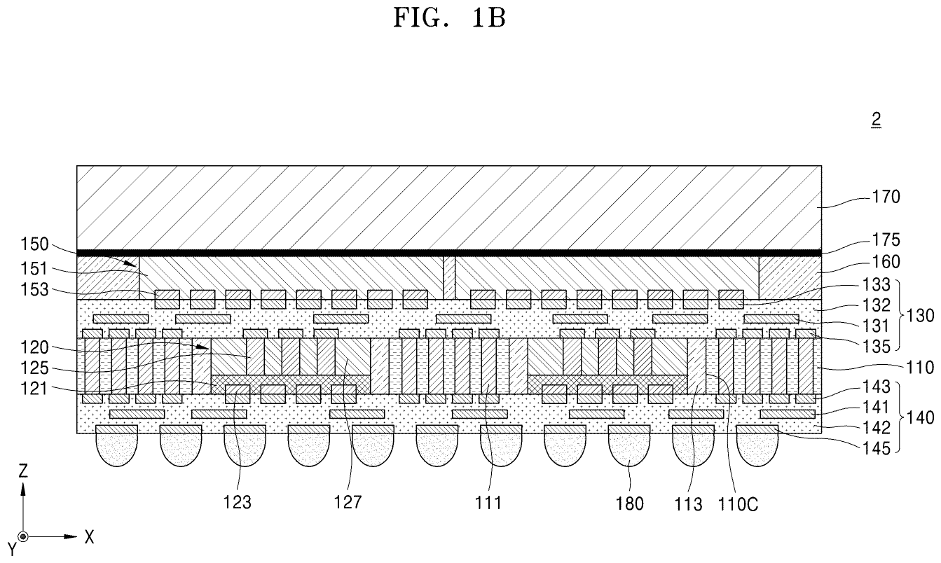

FIGS. 1A and 1B are side cross-sectional views schematically showing a semiconductor package 1, according to one or more embodiments.

Referring to FIG. 1A, the semiconductor package 1 may include a substrate 110, a first semiconductor chip 120, a first redistribution structure 130, a second redistribution structure 140, a second semiconductor chip 150, and a heat dissipation chip 170.

The substrate 110 may include a silicon (Si) wafer including, for example, crystalline silicon, polycrystalline silicon, or amorphous silicon. Also, the substrate 110 may include semiconductor elements, such as germanium (Ge), or compound semiconductors, such as silicon carbide (SiC), gallium arsenide (GaAs), indium arsenide (InAs), and indium phosphide (InP).

The substrate 110 may include a plurality of through-holes 110C. Two adjacent through-holes 110C may be spaced apart from each other by a certain distance in a horizontal direction. Although FIG. 1A illustrates that the two adjacent through-holes 110C are spaced apart from each other in a first horizontal direction X, other two adjacent through-holes 110C may be spaced apart from each other in a second horizontal direction Y intersecting the first horizontal direction X. The through-holes 110C may each have a certain depth. The through-holes 110C may have the same width and depth.

A plurality of first semiconductor chips 120 may be disposed inside the through-holes 110C, respectively. The first semiconductor chips 120 may each include a first semiconductor substrate 127, a first device layer 121, a first chip pad 123, and a through-electrode 125.

The first semiconductor chip 120 may include a memory chip. Accordingly, the first semiconductor chip 120 may include a plurality of memory devices therein. The first semiconductor chip 120 may include, for example, a volatile memory device, such as dynamic random access memory (DRAM) or static random access memory (SRAM), or a non-volatile memory device, such as flash memory. In the semiconductor package 1, the first semiconductor chip 120 may include, for example, an SRAM device.

The first semiconductor substrate 127 may have an upper surface and a lower surface that are opposite to each other. The upper surface of the first semiconductor substrate 127 may face the first redistribution structure 130 and the lower surface of the first semiconductor substrate 127 may face the second redistribution structure 140. The upper surface of the first semiconductor substrate 127 may be referred to as an inactive surface and the lower surface of the first semiconductor substrate 127 may be referred to as an active surface.

The first semiconductor substrate 127 may include silicon, for example, crystalline silicon, polycrystalline silicon, or amorphous silicon. Also, the first semiconductor substrate 127 may include semiconductor elements, such as germanium (Ge), or compound semiconductors, such as silicon carbide (SiC), gallium arsenide (GaAs), indium arsenide (InAs), and indium phosphide (InP). The first semiconductor substrate 127 may have a silicon on insulator (SOI) structure. For example, the first semiconductor substrate 127 may include a buried oxide (BOX) layer. The first semiconductor substrate 127 may include a conductive region, for example, a well doped with impurities or a structure doped with impurities. Also, the first semiconductor substrate 127 may include various device isolation structures, such as a shallow trench isolation (STI) structure.

The first device layer 121 may include a wiring pattern that is electrically connected to a plurality of semiconductor devices formed on the first semiconductor substrate 127. The wiring pattern may include a metal wiring layer and a via plug. For example, the wiring pattern may have a multi-layer structure in which two or more metal wiring layers or two or more via plugs are alternately stacked on each other.

The first device layer 121 may be formed on the lower surface, which is the active surface, of the first semiconductor substrate 127. The first device layer 121 may be disposed below the first semiconductor substrate 127. The first semiconductor substrate 127 may be spaced apart from the second redistribution structure 140 in a vertical direction Z with the first device layer 121 therebetween.

A plurality of through-electrodes 125 may pass through the first semiconductor substrate 127 and a portion of the first device layer 121. The through-electrodes 125 may each extend in the vertical direction Z from the first device layer 121 toward the upper surface of the first semiconductor substrate 127 and be electrically connected to the wiring pattern provided in the first device layer 121. The through-electrode 125 may pass through the first semiconductor substrate 127 and electrically connect a wiring line of the first redistribution structure 130 and a wiring line of the first device layer 121 to each other.

The through-electrode 125 may have a pillar shape. The through-electrode 125 has a structure that passes through silicon constituting the first semiconductor substrate 127 and may be thus referred to as a through silicon via (TSV).

A plurality of first chip pads 123 may be disposed on the lower surface of the first device layer 121 and electrically connected to the wiring pattern inside the first device layer 121. The first chip pads 123 may be electrically connected to the through-electrode 125 via the wiring pattern.

An adhesive layer 113 may fill the inside of the through-hole 110C of the substrate 110. Specifically, the adhesive layer 113 may surround the first semiconductor chip 120 accommodated inside the through-hole 110C of the substrate 110. The adhesive layer 113 may attach the first semiconductor chip 120 to the inside of the through-hole 110C. Here, an upper surface of the adhesive layer 113 may be at the same level as an upper surface of the substrate 110 and an upper surface of the first semiconductor chip 120.

The adhesive layer 113 may include any one of SiO, SiON, SiCN, SiCO, and a polymer material. The polymer material may include benzocyclobutene (BCB), polyimide (PI), polybenzoxazole (PBO), silicone, acrylate, or epoxy. For example, the adhesive layer 113 may include silicon oxide. For example, the adhesive layer 113 may attach the first semiconductor chip 120 to the substrate 110 through oxide bonding.

The substrate 110 may include a plurality of through-vias 111. The through-vias 111 may be arranged between the first semiconductor chips 120. The through-vias 111 may pass through the substrate 110 in the vertical direction Z between adjacent through-holes 110C. The through-vias 111 may each have a pillar shape extending in the vertical direction Z. Two adjacent through-vias 111 may be spaced apart from each other by a certain distance in the horizontal direction.

Although FIG. 1A shows that four through-vias 111 are arranged between two adjacent first semiconductor chips 120, the disclosure is not limited thereto. For example, more or less than four through-vias 111 may be arranged between two adjacent first semiconductor chips 120.

The through-vias 111 may electrically connect the second redistribution structure 140 to the first redistribution structure 130. For example, upper surfaces of the through-vias 111 may be connected to first lower connection pads 135 of the first redistribution structure 130 and lower surfaces of the through-vias 111 may be connected to second upper connection pads 143 of the second redistribution structure 140, respectively. The upper surfaces of the through-vias 111 may be coplanar with the upper surface of the substrate 110, and the lower surfaces of the through-vias 111 may be coplanar with a lower surface of the substrate 110.

The through-vias 111 may include copper (Cu) or a copper (Cu) alloy. Accordingly, the through-vias 111 may be referred to as Cu vias. However, the material of the through-via 111 is not limited to Cu. The through-vias 111 may surround the first semiconductor chips 120.

The through-vias 111 may surround the first semiconductor chip 120 with the material forming the substrate 110 therebetween. The through-vias 111 may function as heat dissipation vias. For example, the through-vias 111 may discharge heat generated in the first semiconductor chip 120 to the outside through the second redistribution structure 140 and a plurality of external connection terminals 180. Also, the through-vias 111 may discharge heat from the second semiconductor chip 150 to the outside through the first redistribution structure 130. For example, the through-vias 111 may discharge heat generated in the second semiconductor chip 150 to the outside through the first redistribution structure 130, the second redistribution structure 140, and the external connection terminals 180.

The first semiconductor chip 120 may be disposed in the through-hole 110C formed in the substrate 110, and thus, the heat generated inside the semiconductor package 1 may be effectively discharged. Also, the through-vias 111 are arranged around the first semiconductor chip 120, and thus, the heat generated inside the semiconductor package 1 may be effectively discharged.

The first redistribution structure 130 may be disposed on the upper surface of the substrate 110. The first redistribution structure 130 may include at least one first insulating layer 132 and at least one first circuit wiring layer 131 disposed therein. For example, a first circuit wiring layer 131 may be disposed between two vertically adjacent first insulating layers 132. The first redistribution structure 130 may include a redistribution substrate formed by a redistribution process. However, the first redistribution structure 130 may include, but not limited to, any one of a printed circuit board (PCB), a metal core PCB (MCPCB), a metal PCB (MPCB), and a flexible PCB (FPCB).

The first insulating layers 132 may include a polymer material, for example, photo imageable dielectric (PID), photosensitive polyimide (PSPI), glass fiber-cured epoxy resin, polyimide resin, Teflon resin, etc.

The first circuit wiring layer 131 may include a wiring layer and a via. The wiring layer may extend in the horizontal direction between the first insulating layers 132 and may be at a plurality of vertical levels. The via may be disposed between a plurality of wiring layers at different vertical levels and connect the wiring layers to each other. In embodiments, the wiring layer and the via may include at least one of copper (Cu), nickel (Ni), gold (Au), platinum (Pt), titanium (Ti), chromium (Cr), and an alloy thereof.

The first redistribution structure 130 may include the first lower connection pads 135. The first lower connection pads 135 may be disposed on a lower surface of the first redistribution structure 130. The first lower connection pads 135 may be electrically connected to the first semiconductor chips 120 and the through-vias 111.

The first redistribution structure 130 may include first upper connection pads 133. The first upper connection pads 133 may be disposed on an upper surface of the first redistribution structure 130. The first upper connection pads 133 may be electrically connected to the second semiconductor chip 150.

The second redistribution structure 140 may be disposed on the lower surface of the substrate 110. The second redistribution structure 140 may include at least one second insulating layer 142 and a second circuit wiring layer 141 disposed therein. For example, a second circuit wiring layer 141 may be disposed between two vertically adjacent second insulating layers 142. The second redistribution structure 140 may include a redistribution substrate formed by a redistribution process. However, the second redistribution structure 140 may include, but not limited to, any one of a PCB, an MCPCB, an MPCB, and a FPCB.

The second insulating layers 142 may include a polymer material, for example, PID, PSPI, glass fiber-cured epoxy resin, polyimide resin, Teflon resin, etc.

The second circuit wiring layer 141 may include a wiring layer and a via. The wiring layer may extend in the horizontal direction between the second insulating layers 142 and may be at a plurality of vertical levels. The via may be disposed between a plurality of wiring layers at different vertical levels and connect the wiring layers to each other. In embodiments, the wiring layer and the via may include at least one of copper (Cu), nickel (Ni), gold (Au), platinum (Pt), titanium (Ti), chromium (Cr), and an alloy thereof.

The second redistribution structure 140 may include second lower connection pads 145. The second lower connection pads 145 may be disposed on a lower surface of the second redistribution structure 140. The second lower connection pads 145 may be electrically connected to the external connection terminals 180, respectively.

The second redistribution structure 140 may include second upper connection pads 143. The second upper connection pads 143 may be disposed on an upper surface of the second redistribution structure 140. The second upper connection pads 143 may be electrically connected to the first semiconductor chips 120 and the through-vias 111.

The first redistribution structure 130 may be disposed on the substrate 110 and the first semiconductor chip 120, and the first redistribution structure 130 may be directly bonded to the substrate 110 and the first semiconductor chip 120. The direct bonding may represent diffusion bonding in which conductive material layers facing each other are expanded by heat and integrated with each other by diffusion of metal atoms present therein. For example, the direct bonding may include a case in which facing conductive components of the two parts are directly bonded to each other and a case in which facing insulating components of the two parts are directly bonded to each other. The direct bonding of insulating components may include forming a chemical bond between the insulating components. Here, the direct bonding may include hybrid bonding.

For example, one of the first lower connection pads 135 of the first redistribution structure 130 may be disposed directly on one of the through-electrodes 125 of the first semiconductor chip 120 and directly bonded to the through-electrode 125. During the direct bonding process, metal atoms in the first lower connection pad 135 may diffuse into the through-electrode 125 and metal atoms in the through-electrode 125 may diffuse into the first lower connection pad 135. Therefore, an interface, a barrier or a connection surface between the first lower connection pad 135 and the through-electrode 125 may not exist or may not be identified. Accordingly, the first lower connection pad 135 and the through-electrode 125 may be firmly coupled to each other. In FIG. 1A, a line shown between the first lower connection pad 135 and the through-electrode 125 may be a virtual interface.

As another example, another one of the first lower connection pads 135 of the first redistribution structure 130 may be disposed directly on another one of the through-vias 111 of the substrate 110 and directly bonded to the through-via 111. During the direct bonding process, metal atoms in the first lower connection pad 135 may diffuse into the through-via 111 and metal atoms in the through-via 111 may diffuse into the first lower connection pad 135. Therefore, an interface, a barrier or a connection surface between the first lower connection pad 135 and the through-via 111 may not exist or may not be identified. Accordingly, the first lower connection pad 135 and the through-via 111 may be firmly coupled to each other. In FIG. 1A, a line shown between the first lower connection pad 135 and the through-vias 111 may be a virtual interface.

The second redistribution structure 140 may be disposed on the substrate 110 and the first semiconductor chip 120, and the second redistribution structure 140 may be directly bonded to the substrate 110 and the first semiconductor chip 120.

For example, one of the second upper connection pads 143 of the second redistribution structure 140 may be disposed directly on one of the first chip pads 123 of the first semiconductor chip 120 and directly bonded to the first chip pad 123. During the direct bonding process, metal atoms in the second upper connection pad 143 may diffuse into the first chip pad 123 and metal atoms in the first chip pad 123 may diffuse into the second upper connection pad 143. Therefore, an interface, a barrier or a connection surface between the second upper connection pad 143 and the first chip pad 123 may not exist or may not be identified. Accordingly, the second upper connection pad 143 and the first chip pad 123 may be firmly coupled to each other. In FIG. 1A, a line shown between the second upper connection pad 143 and the first chip pad 123 may be a virtual interface.

As another example, another one of the second upper connection pads 143 of the second redistribution structure 140 may be disposed directly on another one of the through-vias 111 of the substrate 110 and directly bonded to the through-via 111. During the direct bonding process, metal atoms in the second upper connection pad 143 may diffuse into the through-via 111 and metal atoms in the through-via 111 may diffuse into the second upper connection pad 143. Therefore, an interface, a barrier or a connection surface between the second upper connection pad 143 and the through-via 111 may not exist or may not be identified. Accordingly, the second upper connection pad 143 and the through-via 111 may be firmly coupled to each other. In FIG. 1A, a line shown between the second upper connection pad 143 and the through-via 111 may be a virtual interface.

A plurality of second semiconductor chips 150 may be disposed on the first redistribution structure 130. The second semiconductor chips 150 may each include a plurality of logic devices therein. Here, the logic devices may refer to devices performing various signal processing and include, for example, an AND gate, an OR gate, a NOT gate, a NAND gate, a NOR gate, and/or a flip-flop, not being limited thereto. In the semiconductor package 1, the second semiconductor chip 150 may include, for example, an application processor (AP) chip. Depending on functions, the second semiconductor chip 150 may also be referred to as a control chip, a process chip, a central processing unit (CPU) chip, a graphic processing unit (GPU), or the like.

The second semiconductor chip 150 may include a second semiconductor substrate 151 and a second device layer, but, unlike the first semiconductor chip 120, may not include a through-electrode. The second device layer may include a wiring pattern that is electrically connected to a plurality of semiconductor devices formed on the second semiconductor substrate 151. The wiring pattern may include a metal wiring layer and a via plug. For example, the wiring pattern may have a multi-layer structure in which two or more metal wiring layers or two or more via plugs are alternately stacked on each other.

The second semiconductor substrate 151 may have an upper surface and a lower surface that are opposite to each other. The upper surface of the second semiconductor substrate 151 may face the heat dissipation chip 170 and the lower surface of the second semiconductor substrate 151 may face the first redistribution structure 130. The upper surface of the second semiconductor substrate 151 may be referred to as an inactive surface and the lower surface of the second semiconductor substrate 151 may be referred to as an active surface.

The second semiconductor substrate 151 may include silicon, for example, crystalline silicon, polycrystalline silicon, or amorphous silicon. Also, the second semiconductor substrate 151 may include semiconductor elements, such as germanium (Ge), or compound semiconductors, such as silicon carbide (SiC), gallium arsenide (GaAs), indium arsenide (InAs), and indium phosphide (InP). Here, the second semiconductor substrate 151 may have an SOI structure. For example, the second semiconductor substrate 151 may have a BOX layer. The second semiconductor substrate 151 may include a conductive region, for example, a well doped with impurities or a structure doped with impurities. Also, the second semiconductor substrate 151 may have various device isolation structures, such as an STI structure.

A plurality of second chip pads 153 may be disposed on the lower surface of the second device layer and electrically connected to the wiring pattern inside the second device layer. The second chip pads 153 may be electrically connected to the first redistribution structure 130 via the wiring pattern. The second chip pads 153 may be respectively connected to the first upper connection pads 133.

A sealing material 160 may be disposed between the first redistribution structure 130 and the heat dissipation chip 170. The sealing material 160 may be disposed on side surfaces of the second semiconductor chip 150 and seal the same. An upper surface of the sealing material 160 may be coplanar with an upper surface of the second semiconductor chip 150 and a lower surface of the sealing material 160 may be coplanar with a lower surface of the second semiconductor chip 150. The sealing material 160 may include an insulating material, such as a silicon oxide film, a silicon nitride film, and a silicon oxynitride film.

The second semiconductor chip 150 may be disposed on the first redistribution structure 130, and the second semiconductor chip 150 may be directly bonded to the first redistribution structure 130.

For example, one of the second chip pads 153 of the second semiconductor chip 150 may be disposed directly on one of the first upper connection pads 133 of the first redistribution structure 130 and directly bonded to the first upper connection pad 133. During the direct bonding process, metal atoms in the second chip pad 153 may diffuse into the first upper connection pad 133 and metal atoms in the first upper connection pad 133 may diffuse into the second chip pad 153. Therefore, an interface, a barrier or a connection surface between the second chip pad 153 and the first upper connection pad 133 may not exist or may not be identified. Accordingly, the second chip pad 153 and the first upper connection pad 133 may be firmly coupled to each other. In FIG. 1A, a line shown between the second chip pad 153 and the first upper connection pad 133 may be a virtual interface.

The heat dissipation chip 170 may be disposed on the second semiconductor chip 150 and the sealing material 160. The heat dissipation chip 170 may overlap the first semiconductor chip 120 and the second semiconductor chip 150 in the vertical direction Z. The heat dissipation chip 170 may be stacked directly on the second semiconductor chip 150 and the sealing material 160. The heat dissipation chip 170 may include silicon as a dummy chip. For example, the heat dissipation chip 170 may include a material having high thermal conductivity.

As another example, referring to FIG. 1B, the heat dissipation chip 170 may be stacked on the second semiconductor chip 150 and the sealing material 160 with a thermal interfacial material (TIM) layer 175 therebetween. For example, the TIM layer 175 may include an insulating material or a material including an insulating material and capable of maintaining electrical insulation. The TIM layer 175 may include, for example, an insulating base layer, such as epoxy resin, and a heat dissipating filler contained in the insulating base layer. The TIM layer may 175 include mineral oil, grease, gap filler putty, phase change gel, phase change material pads, or particle filled epoxy.

The heat dissipation chip 170 may be disposed on the second semiconductor chip 150, and thus, heat generated from the second semiconductor chip 150 may be discharged to the outside through the heat dissipation chip 170. Also, the heat generated in the first semiconductor chip 120 may be discharged to the outside through the first redistribution structure 130, the sealing material 160, and the heat dissipation chip 170.

The external connection terminals 180 may be disposed below the second redistribution structure 140. The external connection terminals 180 may be physically connected to an external device, for example, a motherboard. The external connection terminals 180 may be physically connected to the second redistribution structure 140. The external connection terminals 180 may transmit, to an external device, electric signals received from the first semiconductor chip 120 and the second semiconductor chip 150 through the second redistribution structure 140. In addition, the external connection terminals 180 may transmit electric signals received from the external device to the first semiconductor chip 120 and the second semiconductor chip 150. The external connection terminals 180 may include a conductive material, for example, at least one of tin (Sn), silver (Ag), copper (Cu), and aluminum (Al).

In the semiconductor package 1, the first semiconductor chip 120 is located inside the through-hole 110C formed in the substrate 110, the through-vias 111 are arranged around the first semiconductor chip 120, and the heat dissipation chip 170 is disposed on the second semiconductor chip 150. Accordingly, the heat generated inside the semiconductor package 1 may be effectively discharged.

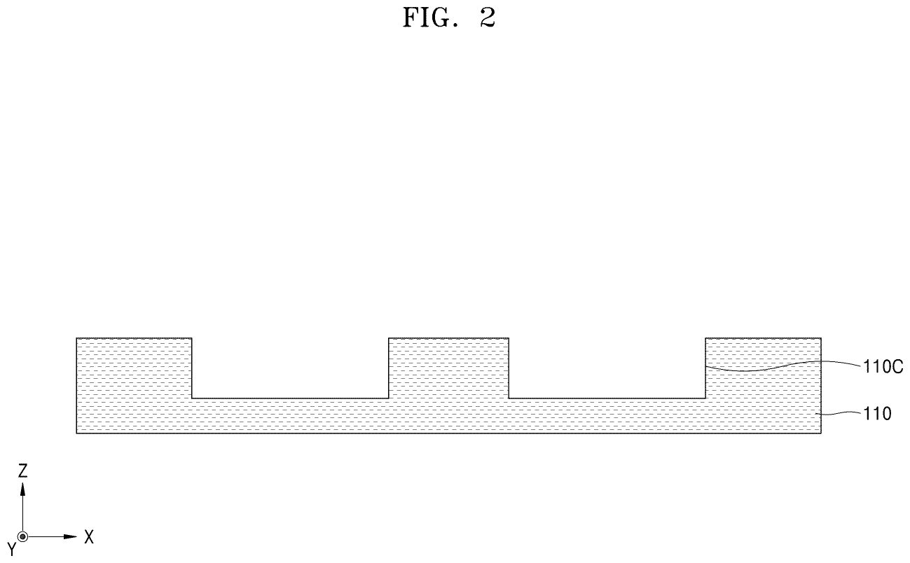

FIGS. 2 to 14 are cross-sectional views schematically showing a method of manufacturing the semiconductor package shown in FIG. 1A, according to one or more embodiments.

Referring to FIG. 2, a semiconductor package manufacturing method according to the embodiments may include preparing a substrate 110 including a plurality of holes 110C. The substrate 110 may include a silicon (Si) wafer including, for example, crystalline silicon, polycrystalline silicon, or amorphous silicon. It is to be understood here that the holes 110C will be formed as through-holes, as shown in FIG. 1A, when a lower portion of the substrate 110 is removed in a later step.

The substrate 110 may include the holes 110C. The holes 110C may be formed in the upper portion of the substrate 110 using an etch mask (not shown). Two adjacent holes 110C may be spaced apart from each other by a certain distance in a horizontal direction. The holes 110C may each have a certain width and depth. The holes 110C may have the same width and depth.

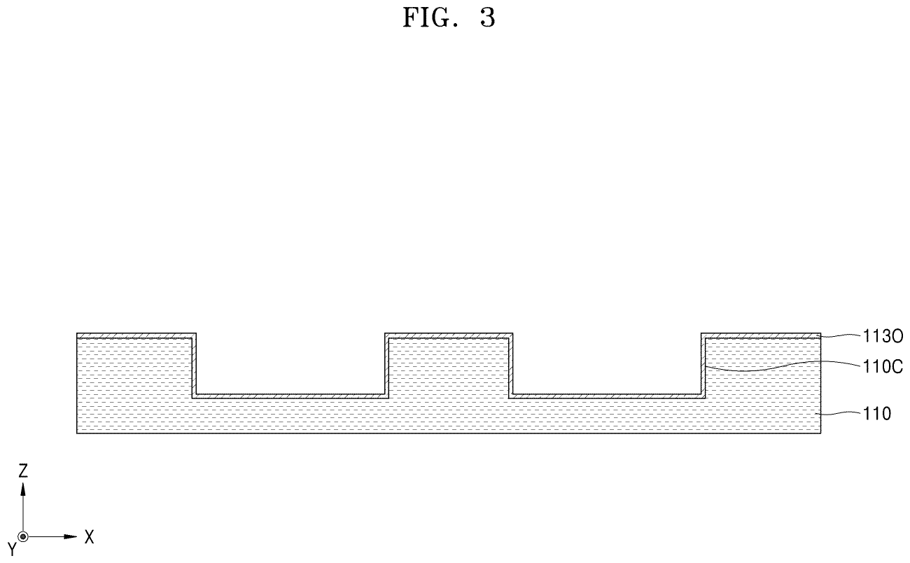

Referring to FIG. 3, a first adhesive layer 113O may be formed on the substrate 110. The first adhesive layer 113O may be conformally formed on an upper surface of the substrate 110. The first adhesive layer 113O may be conformally formed on an inside of the holes 110C. For example, the first adhesive layer 113O may be conformally formed on bottom surfaces and sidewalls of the holes 110C. Here, the first adhesive layer 113O may include any one of SiO, SiON, SiCN, SiCO, and a polymer material.

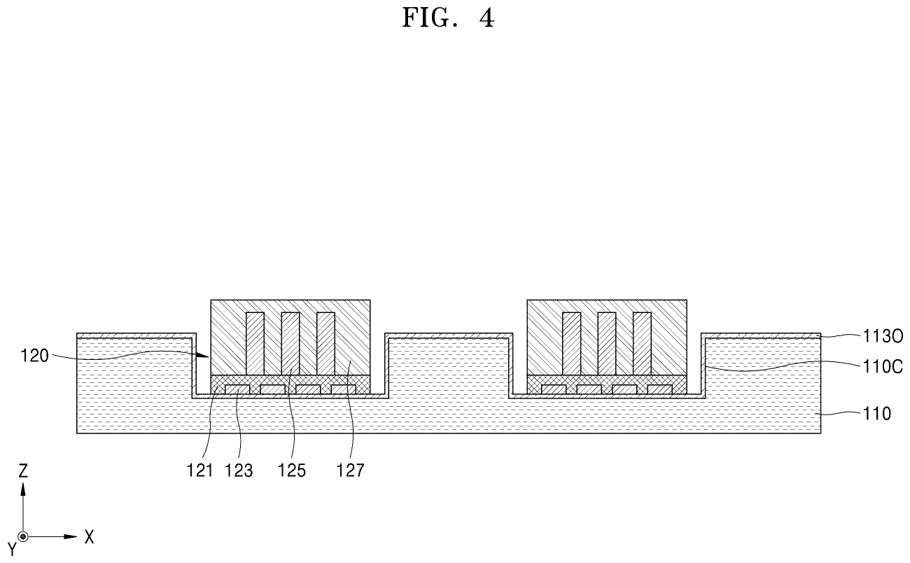

Referring to FIG. 4, a plurality of first semiconductor chips 120 may be provided inside the holes 110C, respectively. The first semiconductor chips 120 may each include a first semiconductor substrate 127, a first device layer 121, at least one first chip pad 123, and at least one through-electrode 125.

The first semiconductor chip 120 may include a memory chip. Accordingly, the first semiconductor chip 120 may include a plurality of memory devices therein. The first semiconductor chip 120 may include, for example, a volatile memory device, such as DRAM or SRAM, or a non-volatile memory device, such as flash memory. For example, the first semiconductor chip 120 may include an SRAM device.

The first semiconductor chips 120 may be attached to the first adhesive layer 113O. The first semiconductor chips 120 and the substrate 110 may be oxide bonded by the first adhesive layer 113O.

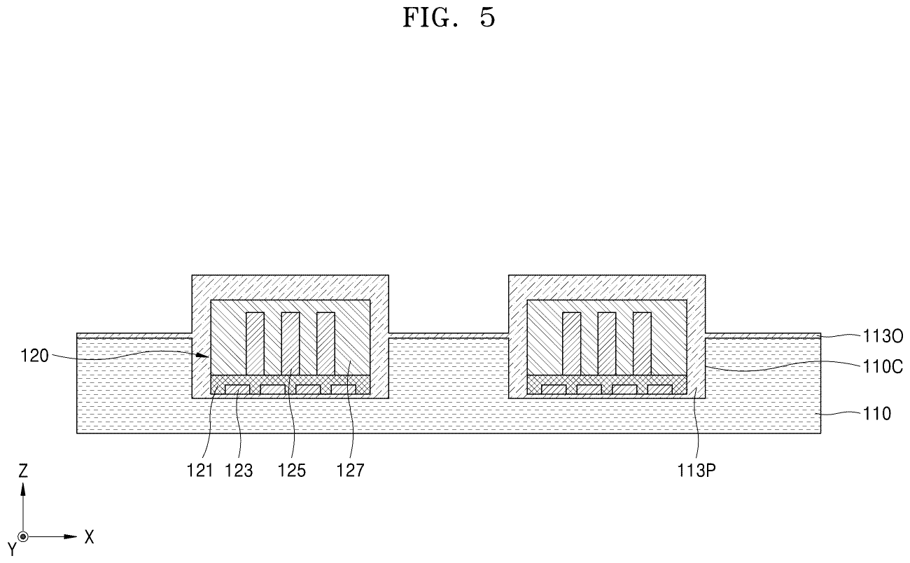

Referring to FIG. 5, a second adhesive layer 113P may be formed. The second adhesive layer 113P may fill the inside of the through-hole 110C of the substrate 110. Specifically, the second adhesive layer 113P may be formed on the first semiconductor chip 120 accommodated inside the through-hole 110C of the substrate 110. The second adhesive layer 113P may fill an empty space inside the through-hole 110C to which the first semiconductor chip 120 is not attached. The second adhesive layer 113P may be formed on the first semiconductor chip 120 and the first adhesive layer 113O. The second adhesive layer 113P may be formed by a chemical vapor deposition (CVD) process.

The second adhesive layer 113P may include any one of SiO, SiON, SiCN, SiCO, and a polymer material. The second adhesive layer 113P and the first adhesive layer 113O may include the same material, but the disclosure is not limited thereto. For example, both the second adhesive layer 113P and the first adhesive layer 113O may include silicon oxide. Also, the second adhesive layer 113P and the first adhesive layer 113O may include different materials.

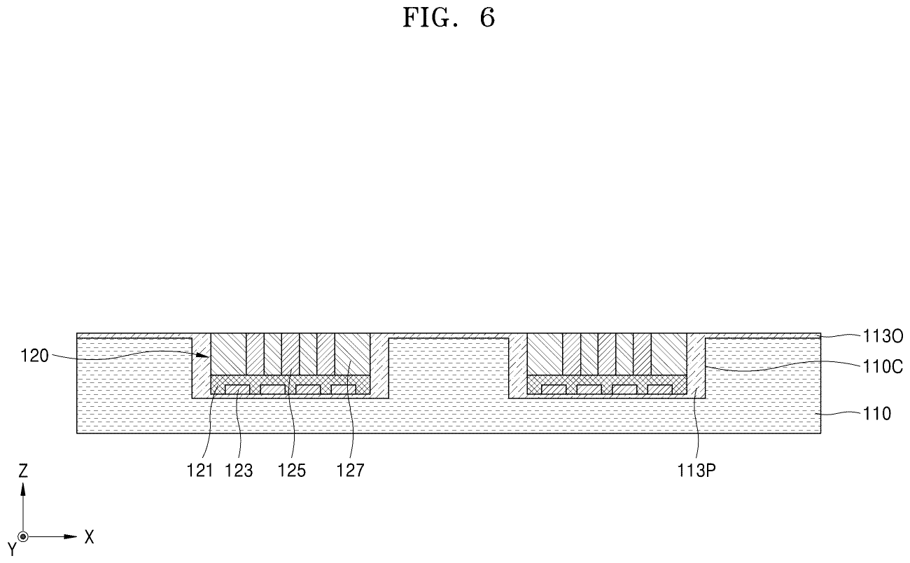

Referring to FIG. 6, a portion of the first semiconductor chip 120, a portion of the second adhesive layer 113P, and a portion of the first adhesive layer 113O may be removed, and a planarization process may be performed thereon. The portion of the first semiconductor chip 120, the portion of the second adhesive layer 113P, and the portion of the first adhesive layer 113O may be removed by a grinding process and a chemical mechanical polishing (CMP) process. Upper surfaces of the first semiconductor chip 120, the second adhesive layer 113P, and the first adhesive layer 113O may be coplanar. The upper surfaces of a plurality of through-electrodes 125 of the first semiconductor chip 120 may be exposed.

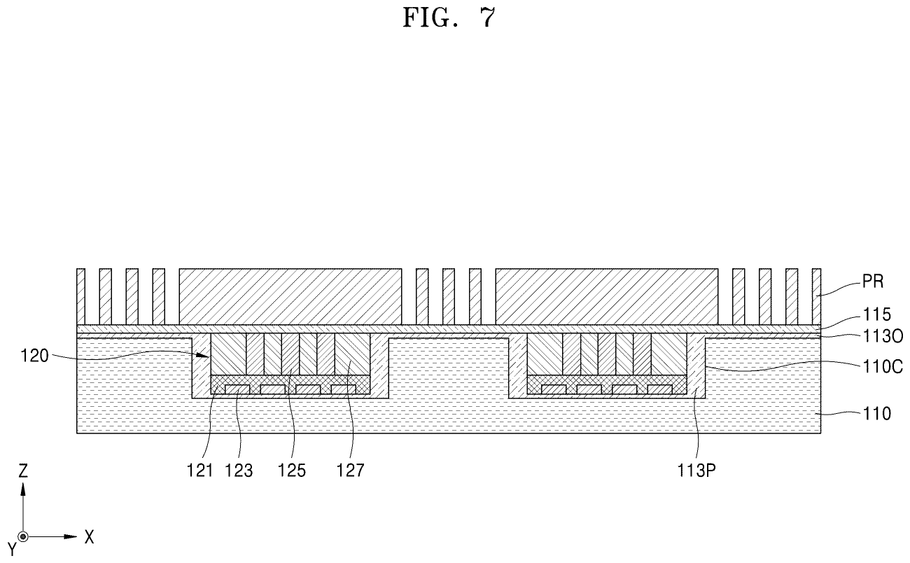

Referring to FIG. 7, an insulating film 115 and a photoresist pattern PR may be formed. The insulating film 115 may be conformally formed on the upper surfaces of the first semiconductor chip 120, the second adhesive layer 113P, and the first adhesive layer 113O. Here, the insulating film 115 may include any one of SiO, SiN, SiON, SiCN, SiCO, and a polymer material. The insulating film 115 may include a material that has etch selectivity with respect to the photoresist pattern PR.

The insulating film 115 may include one or more layers. For example, the insulating film 115 is shown as a single layer in FIG. 7, but the insulating film 115 may also be formed as a double layer structure. The insulating film 115 may be formed by a CVD process, a physical vapor deposition (PVD) process, or an atomic layer deposition (ALD) process.

The process of forming the photoresist pattern PR may include forming a photoresist film (not shown) on the insulating film 115 and performing exposure and development processes on the photoresist film. The photoresist pattern PR may include openings that overlap a plurality of through-vias 111 vertically or in parallel.

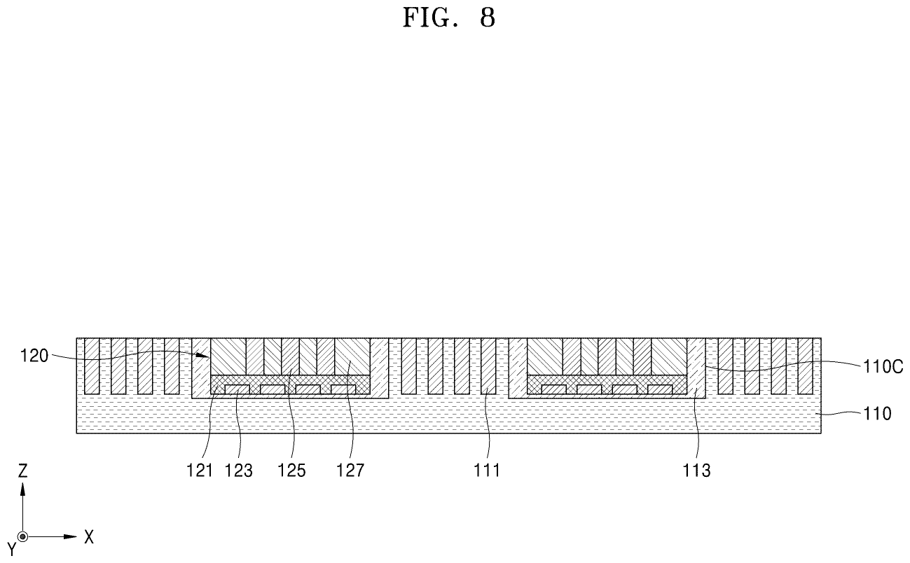

Referring to FIG. 8, a plurality of through-vias 111 may be formed. A plurality of via holes (not shown) may be formed in the substrate 110 using the photoresist pattern PR of FIG. 7, and the through-vias 111 may fill the via holes.

The through-vias 111 may be formed between the first semiconductor chips 120. The through-vias 111 may pass through the substrate 110 in the vertical direction Z between adjacent holes 110C. The through-vias 111 may each have a pillar shape extending in the vertical direction Z. Two adjacent through-vias 111 may be spaced apart from each other by a certain distance in the horizontal direction.

The through-via 111 may each include copper (Cu) or a copper (Cu) alloy. The through-vias 111 may surround the first semiconductor chip 120. The through-via 111 may function as a heat dissipation via.

After the through-vias 111 are formed, planarization may be performed thereon through a CMP process. During this process, the insulating film 115, the first adhesive layer 113O, and a portion of the second adhesive layer 113P may be removed, and the upper surface of the substrate 110, the upper surface of the first semiconductor chip 120, and the upper surfaces of the through-vias 111 may be exposed. In this process, an adhesive layer 113 that fills the inside of the holes 110C may be formed. The upper surfaces of the first semiconductor chip 120, the adhesive layer 113, and the through-vias 111 may be coplanar.

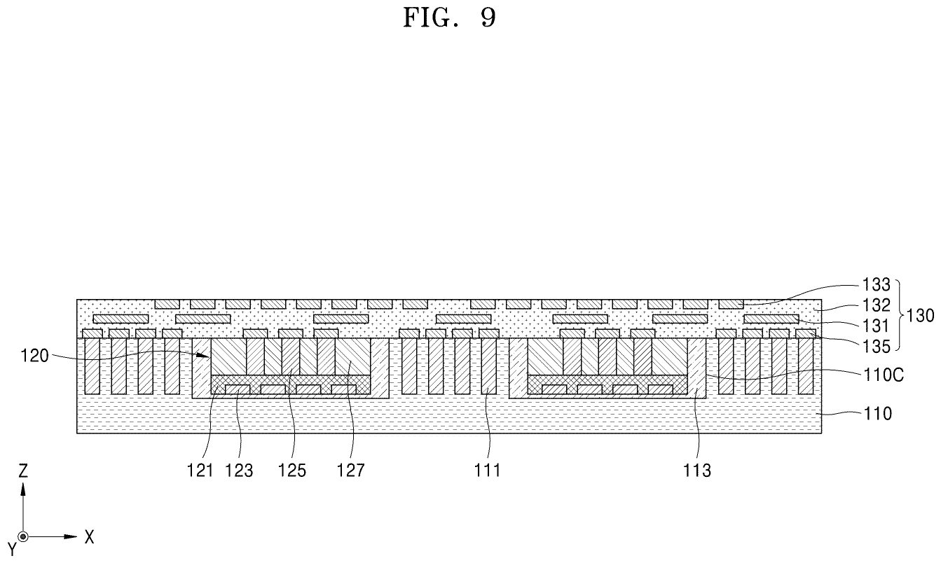

Referring to FIG. 9, a first redistribution structure 130 may be formed on the upper surface of the substrate 110. The first redistribution structure 130 may include a plurality of first insulating layers 132 and at least one first circuit wiring layer 131 disposed between the first insulating layers 132.

To form the first redistribution structure 130, forming of a first insulating layers 132 and forming of a first circuit wiring layer 131 may be repeatedly performed.

The first insulating layers 132 may be formed using a polymer material, for example, PID, PSPI, glass fiber-cured epoxy resin, polyimide resin, Teflon resin, etc. The first circuit wiring layers 131 may be formed using at least one of an electroplating process, an electroless plating process, a sputtering process, or an evaporation process.

For example, in the forming of the first redistribution structure 130, vias may be formed to connect the wiring layers to each other, which are formed at different vertical levels during a process of forming the first circuit wiring layers 131. A plurality of first lower connection pads 135 electrically connected to the first circuit wiring layer 131 may be formed on a lower surface of the first redistribution structure 130. A plurality of first upper connection pad 133 electrically connected to the first circuit wiring layer 131 may be formed on an upper surface of the first redistribution structure 130.

The first redistribution structure 130 may be disposed on the substrate 110 and the first semiconductor chip 120, and the first redistribution structure 130 may be directly bonded to the substrate 110 and the first semiconductor chip 120. The direct bonding may represent diffusion bonding in which conductive material layers facing each other are expanded by heat and integrated with each other by diffusion of metal atoms present therein. Here, the direct bonding may include hybrid bonding.

For example, one of the first lower connection pads 135 of the first redistribution structure 130 may be disposed directly on one of a plurality of through-electrodes 125 of the first semiconductor chip 120 and directly bonded to the through-electrode 125. During the direct bonding process, metal atoms in the first lower connection pad 135 may diffuse into the through-electrode 125 and metal atoms in the through-electrode 125 may diffuse into the first lower connection pad 135. Therefore, an interface, a barrier or a connection surface between the first lower connection pad 135 and the through-electrode 125 may not exist or may not be identified. Accordingly, the first lower connection pad 135 and the through-electrode 125 may be firmly coupled to each other. In FIG. 9, a line shown between the first lower connection pad 135 and the through-electrode 125 may be a virtual interface.

As another example, another one of the first lower connection pads 135 of the first redistribution structure 130 may be disposed directly on another one of the through-vias 111 of the substrate 110 and directly bonded to the through-via 111. During the direct bonding process, metal atoms in the first lower connection pad 135 may diffuse into the through-via 111 and metal atoms in the through-via 111 may diffuse into the first lower connection pad 135. Therefore, an interface, a barrier or a connection surface between the first lower connection pad 135 and the through-via 111 may not exist or may not be identified. Accordingly, the first lower connection pad 135 and the through-via 111 may be firmly coupled to each other. In FIG. 9, a line shown between the first lower connection pad 135 and the through-vias 111 may be a virtual interface.

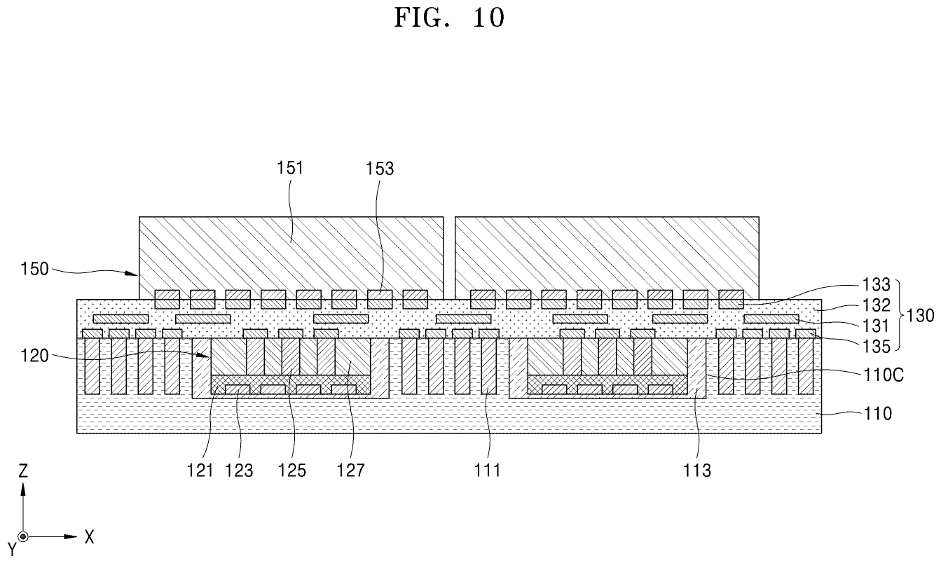

Referring to FIG. 10, a plurality of second semiconductor chips 150 may be attached to the first redistribution structure 130. The second semiconductor chips 150 may each include a plurality of logic devices therein.

The second semiconductor chip 150 may be directly bonded to the first redistribution structure 130. For example, one of a plurality of second chip pads 153 of the second semiconductor chip 150 may be disposed directly on one of the first upper connection pads 133 of the first redistribution structure 130 and directly bonded to the first upper connection pad 133. During the direct bonding process, metal atoms in the second chip pad 153 may diffuse into the first upper connection pad 133 and metal atoms in the first upper connection pad 133 may diffuse into the second chip pad 153. Therefore, an interface, a barrier or a connection surface between the second chip pad 153 and the first upper connection pad 133 may not exist or may not be identified. Accordingly, the second chip pad 153 and the first upper connection pad 133 may be firmly coupled to each other. In FIG. 10, a line shown between the second chip pad 153 and the first upper connection pad 133 may be a virtual interface.

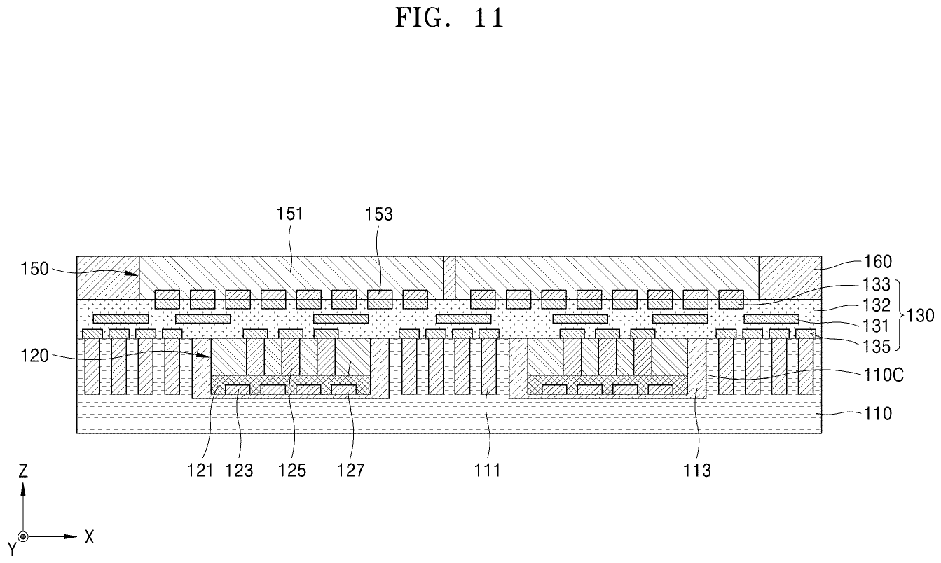

Referring to FIG. 11, a sealing material 160 may be formed on the second semiconductor chip 150. The sealing material 160 may be formed on an upper surface and sidewalls of the second semiconductor chip 150. The sealing material 160 may include an insulating material, such as a silicon oxide film, a silicon nitride film, and a silicon oxynitride film.

Subsequently, a planarization process may be performed thereon. A portion of the second semiconductor chip 150 and a portion of the sealing material 160 may be removed through a grinding process and a CMP process. Through the planarization process, the upper surface of the second semiconductor chip 150 and the upper surface of the sealing material 160 may be coplanar.

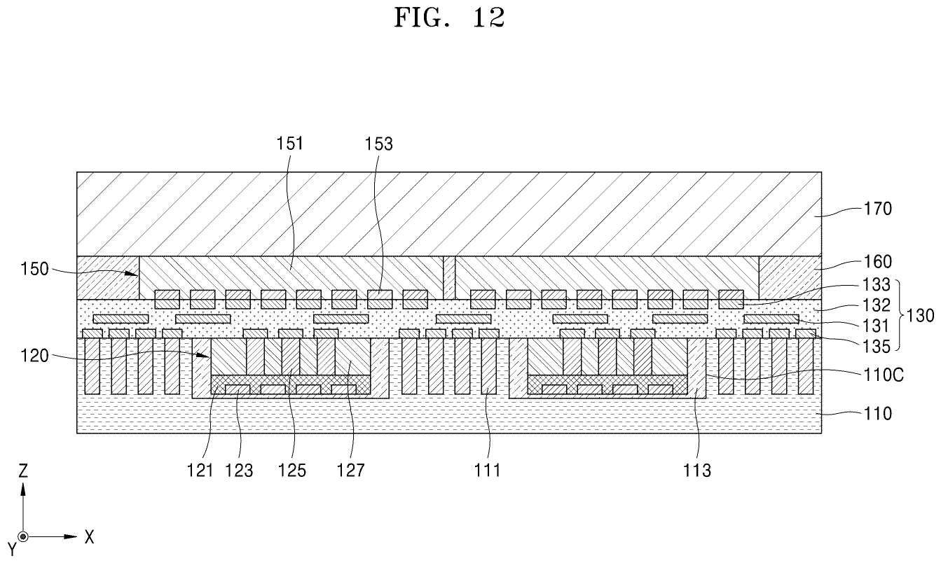

Referring to FIG. 12, a heat dissipation chip 170 may be disposed on the second semiconductor chip 150 and the sealing material 160. The heat dissipation chip 170 may overlap the first semiconductor chip 120 and the second semiconductor chip 150 in the vertical direction Z. The heat dissipation chip 170 may be stacked directly on the second semiconductor chip 150 and the sealing material 160. The heat dissipation chip 170 may include silicon as a dummy chip. For example, the heat dissipation chip 170 may include a material having high thermal conductivity. Also, the heat dissipation chip 170 may be stacked on the second semiconductor chip 150 and the sealing material 160 with a TIM layer 175 therebetween (FIG. 1B).

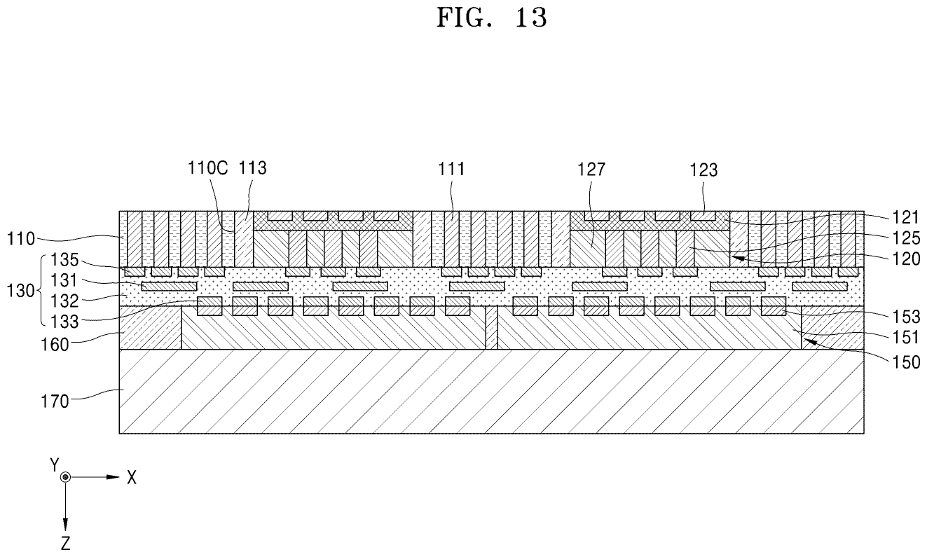

Referring to FIG. 13, a portion of the substrate 110 may be removed. The portion of the substrate 110 may be removed through a grinding process and a CMP process. At this moment, a portion of the adhesive layer 113 may be removed. As the portion of the substrate 110 is removed, the lower surface of the substrate 110, the lower surface of the first semiconductor chip 120, and the lower surfaces of the through-vias 111 may be exposed. Also, a plurality of first chip pad 123 of the first semiconductor chip 120 may be exposed. The lower surface of the substrate 110, the lower surface of the first semiconductor chip 120, and the lower surfaces of the through-vias 111 may be coplanar.

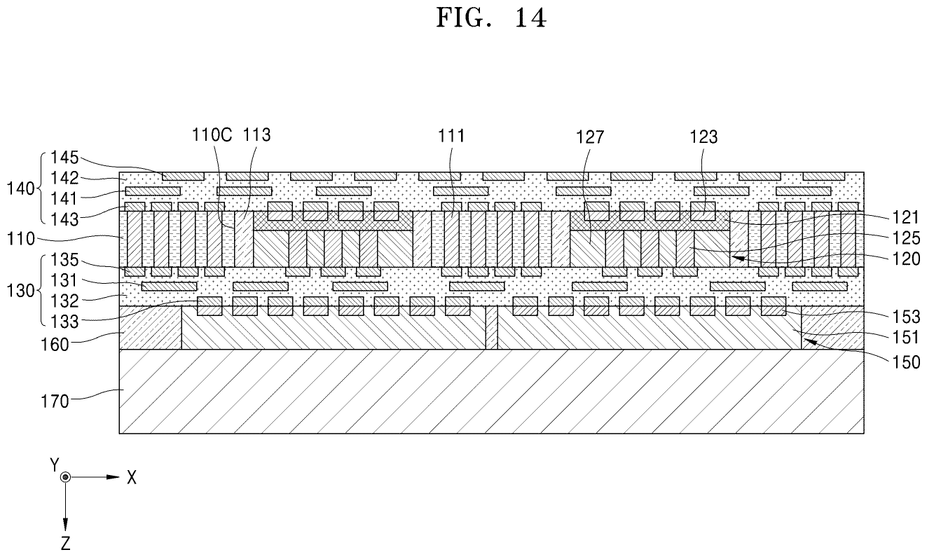

Referring to FIG. 14, a second redistribution structure 140 may be formed on the lower surface of the substrate 110. The second redistribution structure 140 may include a plurality of second insulating layers 142 and a second circuit wiring layer 141 located between the second insulating layers 142.

To form the second redistribution structure 140, forming of a second insulating layer 142 and forming of a second circuit wiring layer 141 may be repeatedly performed.

The second insulating layers 142 may be formed using a polymer material, for example, PID, PSPI, glass fiber-cured epoxy resin, polyimide resin, Teflon resin, etc. The second circuit wiring layers 141 may be formed using at least one of an electroplating process, an electroless plating process, a sputtering process, or an evaporation process.

For example, in the forming of the second redistribution structure 140, vias may be formed to connect the wiring layers to each other, which are formed at different vertical levels during a process of forming the second circuit wiring layers 141. A second lower connection pad 145 electrically connected to the second circuit wiring layer 141 may be formed on a lower surface of the second redistribution structure 140. A second upper connection pad 143 electrically connected to the second circuit wiring layer 141 may be formed on an upper surface of the second redistribution structure 140.

For example, one of a plurality of second upper connection pads 143 of the second redistribution structure 140 may be disposed directly on one of the first chip pad 123 of the first semiconductor chip 120 and directly bonded to the first chip pad 123. During the direct bonding process, metal atoms in the second upper connection pad 143 may diffuse into the first chip pad 123 and metal atoms in the first chip pad 123 may diffuse into the second upper connection pad 143. Therefore, an interface, a barrier or a connection surface between the second upper connection pad 143 and the first chip pad 123 may not exist or may not be identified. Accordingly, the second upper connection pad 143 and the first chip pad 123 may be firmly coupled to each other. In FIG. 14, a line shown between the second upper connection pad 143 and the first chip pad 123 may be a virtual interface.

As another example, one of the second upper connection pads 143 of the second redistribution structure 140 may be disposed directly on one of the through-vias 111 of the substrate 110 and directly bonded to the through-via 111. During the direct bonding process, metal atoms in the second upper connection pad 143 may diffuse into the through-via 111 and metal atoms in the through-via 111 may diffuse into the second upper connection pad 143. Therefore, an interface, a barrier or a connection surface between the second upper connection pad 143 and the through-via 111 may not exist or may not be identified. Accordingly, the second upper connection pad 143 and the through-via 111 may be firmly coupled to each other. In FIG. 14, a line between the second upper connection pad 143 and the through-via 111 may be a virtual interface.

Subsequently, referring back to FIG. 1A, external connection terminals 180 are disposed below the second redistribution structure 140, and as a result, the semiconductor package 1 shown in FIG. 1A may be manufactured.

While the disclosure has been particularly shown and described with reference to embodiments thereof, it will be understood that various changes in form and details may be made therein without departing from the spirit and scope of the following claims.

What is claimed is:

1. A semiconductor package comprising:
a substrate comprising a through-hole;
a first semiconductor chip in the through-hole;
an adhesive layer on a side surface of the first semiconductor chip in the through-hole;
a first redistribution structure on an upper surface of the substrate and bonded and connected to the substrate;
a second redistribution structure on a lower surface of the substrate and bonded and connected to the substrate;
a second semiconductor chip on the first redistribution structure; and
a through-via spaced apart from the first semiconductor chip in a horizontal direction and passing through the substrate in a vertical direction.

2. The semiconductor package of claim 1, wherein the adhesive layer comprises silicon oxide.

3. The semiconductor package of claim 1, further comprising a heat dissipation chip overlapping the first semiconductor chip and the second semiconductor chip in the vertical direction.

4. The semiconductor package of claim 3, further comprising a thermal interfacial material (TIM) layer between the heat dissipation chip and the second semiconductor chip.

5. The semiconductor package of claim 1, wherein the first semiconductor chip comprises:
a first semiconductor substrate;
a first device layer on a lower surface of the first semiconductor substrate;
a first chip pad on a lower surface of the first device layer and connected to the second redistribution structure; and
a through-electrode passing through the first semiconductor substrate in the vertical direction and connected to the first redistribution structure.

6. The semiconductor package of claim 5, wherein the first redistribution structure comprises a first lower connection pad directly bonded and connected to the through-electrode and the through-via.

7. The semiconductor package of claim 6, wherein the second semiconductor chip comprises a second semiconductor substrate and a second chip pad connected to the first redistribution structure, and
wherein the first redistribution structure further comprises a first upper connection pad directly bonded and connected to the second chip pad.

8. The semiconductor package of claim 5, wherein the second redistribution structure comprises a second upper connection pad directly bonded and connected to the first chip pad and the through-via.

9. The semiconductor package of claim 1, wherein the first semiconductor chip comprises a memory device, and
wherein the second semiconductor chip comprises a logic device.

10. The semiconductor package of claim 1, further comprising a sealing material on a side surface of the second semiconductor chip,
wherein an upper surface of the sealing material and an upper surface of the second semiconductor chip are coplanar.

11. A method of manufacturing a semiconductor package, the method comprising:
preparing a substrate comprising a hole;
forming an adhesive layer on the substrate and attaching a first semiconductor chip into the hole using the adhesive layer;
forming a through-via spaced apart from the first semiconductor chip in a horizontal direction and passing through the substrate in a vertical direction;
forming a first redistribution structure on an upper surface of the substrate such that the first redistribution structure is directly bonded and connected to the substrate;
attaching a second semiconductor chip onto the first redistribution structure such that the second semiconductor chip is directly bonded and connected to the first redistribution structure; and
forming a second redistribution structure on a lower surface of the substrate such that the second redistribution structure is directly bonded and connected to the substrate.

12. The method of claim 11, further comprising disposing a heat dissipation chip on the second semiconductor chip such that the heat dissipation chip overlaps the first semiconductor chip and the second semiconductor chip in the vertical direction.

13. The method of claim 11, wherein the forming the first redistribution structure comprises forming a first insulating layer, a first circuit wiring layer, a first upper connection pad, and a first lower connection pad, and
wherein the first lower connection pad is directly bonded and connected to a through-electrode of the first semiconductor chip and the through-via of the substrate.

14. The method of claim 13, wherein the attaching the second semiconductor chip comprises directly bonding and connecting a second chip pad of the second semiconductor chip to the first upper connection pad of the first redistribution structure.

15. The method of claim 11, wherein the forming the second redistribution structure comprises forming a second insulating layer, a second circuit wiring layer, a second upper connection pad, and a second lower connection pad,
wherein the second upper connection pad is directly bonded and connected to a first chip pad of the first semiconductor chip and the through-via of the substrate.

16. The method of claim 11, wherein the forming the through-via comprises forming a via hole that pass through the substrate in the vertical direction and forming the through-via in the via hole.

17. A semiconductor package comprising:
a substrate comprising a through-hole;
a through-via spaced apart from the through-hole in a horizontal direction and passing through the substrate in a vertical direction;
a first semiconductor chip in the through-hole, the first semiconductor chip comprising a memory device;
an adhesive layer on a side surface of the first semiconductor chip in the through-hole;
a first redistribution structure on an upper surface of the substrate, the first redistribution structure comprising a first insulating layer, a first circuit wiring layer, a first upper connection pad, and a first lower connection pad;
a second redistribution structure on a lower surface of the substrate, the second redistribution structure comprising a second insulating layer, a second circuit wiring layer, a second upper connection pad, and a second lower connection pad;
a second semiconductor chip on the first redistribution structure and comprising a logic device; and
a heat dissipation chip overlapping the first semiconductor chip and the second semiconductor chip in the vertical direction,
wherein the first redistribution structure, the first semiconductor chip, the second redistribution structure, and the second semiconductor chip are stacked in the vertical direction,
wherein the first semiconductor chip is directly bonded and connected to the first redistribution structure and the second redistribution structure,
wherein the through-via is directly bonded and connected to the first redistribution structure and the second redistribution structure, and
wherein the second semiconductor chip is directly bonded and connected to the first redistribution structure.

18. The semiconductor package of claim 17, wherein the through-via is connected to the first lower connection pad and the second upper connection pad.

19. The semiconductor package of claim 17, wherein the first semiconductor chip comprises:
a through-electrode directly bonded to the first lower connection pad; and
a first chip pad directly bonded to the second upper connection pad.

20. The semiconductor package of claim 18, wherein the second semiconductor chip further comprises a second chip pad directly bonded to the first upper connection pad.
